(19) United States
(12) Patent Application Publication
(10) Pub. No.: US 2011/0141695 A1
(43) Pub. Date: Jun. 16, 2011

(54) ELECTRONIC DEVICE

(75) Inventors: Masashi MIKAMI, Ome-shi (JP); Toshikazu KONNO, Ome-shi (JP)

(73) Assignee: KABUSHIKI KAISHA TOSHIBA, Tokyo (JP)

(21) Appl. No.: 12/908,742

(22) Filed: Oct. 20, 2010

(30) Foreign Application Priority Data
Dec. 15, 2009 (JP) 2009-284301

(51) Int. Cl. H05K 7/20

(52) U.S. Cl. 361/707

(57) ABSTRACT

According to one embodiment, an electronic device includes a circuit board, a heat generating element, a heat dissipater, and a pushing member. The circuit board is housed in a housing. The heat generating element is mounted on the circuit board. The heat dissipator is configured to dissipate heat generated by the heat generating element. The pushing member is configured to push part of the heat dissipator against the heat generating element. At least part of the pushing member is attached to a structure other than the circuit board.

### CROSS-REFERENCE TO RELATED APPLICATIONS

This application is based upon and claims the benefit of priority from Japanese Patent Application No. 2009-284301, filed on Dec. 15, 2010, the entire contents of which are incorporated herein by reference.

### FIELD

Embodiments described herein relate generally to an electronic device.

### BACKGROUND

For example, Japanese Patent Application Publication (KOKAI) No. 2009-080567 discloses a conventional electronic device having a structure to dissipate heat generated by a device mounted on a circuit board through a heat pipe, a heat dissipator, a heat receiver on the device, and the like. In this structure, at least one of the heat receiver and the heat pipe is pushed against the device by a pushing member that is located on the device and attached to the circuit board.

In the conventional electronic device, a component or a wiring pattern cannot be arranged in an area of the circuit board where the pushing member is attached. That is, the area reduces the efficiency of mounting on the circuit board.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of an electronic device according to a first embodiment;

FIG. 2 is an exemplary plan view of the inside of the housing of the electronic device in the first embodiment;

FIG. 3 is an exemplary side view (cross-sectional view) of the inside of the housing viewed in a direction Va of FIG. 2 in the first embodiment;

FIG. 4 is an exemplary plan view of a reinforcing member in the first embodiment;

FIG. 5 is an exemplary plan view of the inside of the housing of an electronic device according to a second embodiment;

FIG. 6 is an exemplary side view (cross-sectional view) of the inside of the housing viewed in a direction Va of FIG. 5 in the second embodiment;

FIG. 7 is an exemplary side view (cross-sectional view) of the inside of the housing of an electronic device according to a third embodiment;

FIG. 8 is an exemplary plan view of the inside of the housing in the third embodiment;

FIG. 9 is an exemplary side view (cross-sectional view) of the inside of the housing of an electronic device according to a fourth embodiment;

FIG. 10 is an exemplary plan view of a reinforcing member and a board supporting member in the fourth embodiment;

FIG. 11 is an exemplary side view (cross-sectional view) of the inside of the housing of an electronic device according to a fifth embodiment; and

FIG. 12 is an exemplary plan view of a reinforcing member in the fifth embodiment.

### DETAILED DESCRIPTION

In general, according to one embodiment, an electronic device comprises a circuit board, a heat generating element, a heat dissipater, and a pushing member. The circuit board is housed in a housing. The heat generating element is mounted on the circuit board. The heat dissipator is configured to dissipate heat generated by the heat generating element. The pushing member is configured to push part of the heat dissipator against the heat generating element. At least part of the pushing member is attached to a structure other than the circuit board.

Embodiments will be set forth in detail with reference to the drawings, in which like reference numerals refer to like elements throughout, and a redundant description will not be provided.

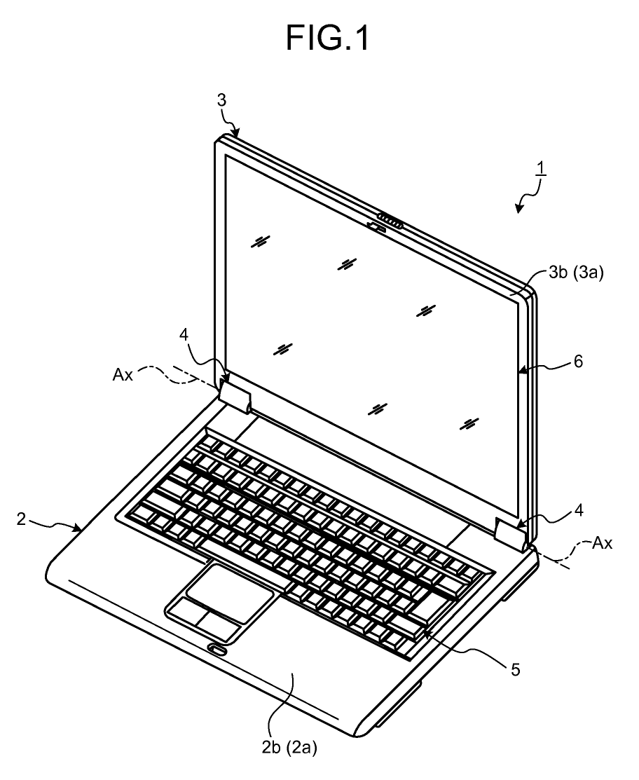

With reference to FIGS. 1 to 4, a description will be given of an electronic device 1 according to a first embodiment.

As illustrated in FIG. 1, the electronic device 1 of the first embodiment is, for example, a notebook personal computer. The electronic device 1 comprises a flat rectangular first body 2 and a flat rectangular second body 3. The first body 2 and the second body 3 are connected by a hinge mechanism 4 to be relatively rotatable about a rotation axis Ax between a closed position (not illustrated) and an open position (FIG. 1).

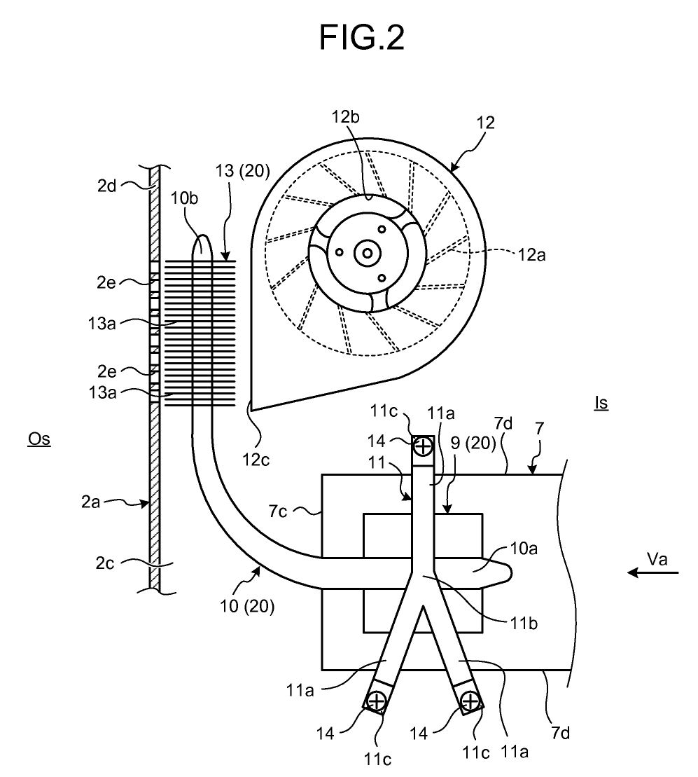

The first body 2 comprises a housing 2a that houses a circuit board 7 (see FIG. 2), a hard disk, a cool air blower mechanism (see FIG. 2), and the like. The circuit board is mounted with a central processing unit (CPU), a read only memory (ROM), a random access memory (RAM), and other electronic components. The first body 2 is provided with a keyboard 5 as an input device on a front surface 2b. On the other hand, the second body 3 is provided with a liquid crystal display (LCD) panel 6 as a display device on a front surface 3b. When the first body 2 and the second body 3 are in the closed position, the front surface 2b of the housing 2a of the first body 2 faces the front surface 3b of a housing 3a of the second body 3, and the keyboard 5 faces the LCD panel 6. On the other hand, in the open position, the front surfaces 2b and 3b are exposed as illustrated in FIG. 1, and the keyboard 5 and the LCD panel 6 are exposed to allow the user to use them. The keyboard 5 and the LCD panel 6 are electronic components.

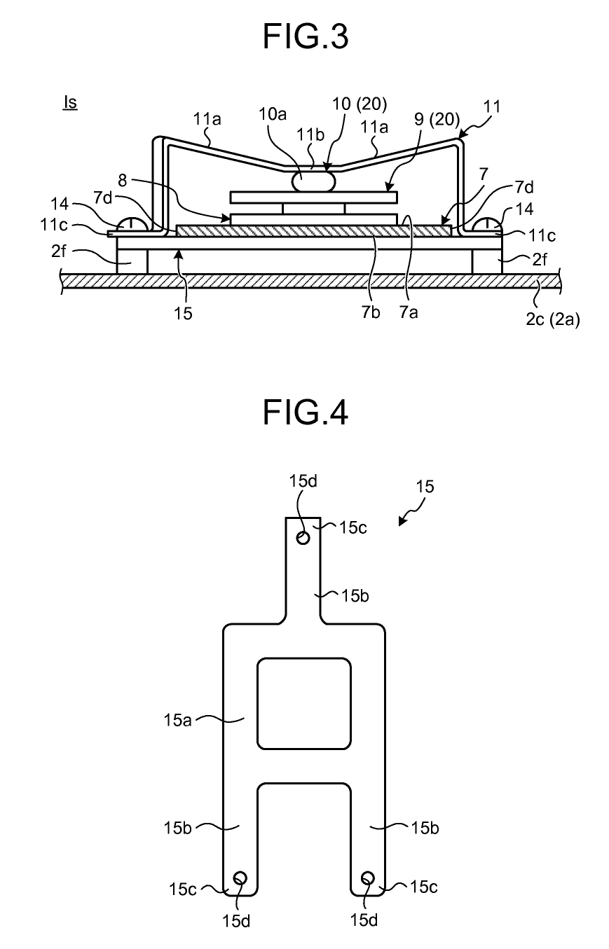

As illustrated in FIGS. 2 and 3, the circuit board 7 is housed in the housing 2a (inside Is). In the plan view illustrated in FIG. 2, the circuit board 7 is formed into a rectangle having short sides 7c (only one of them is illustrated in FIG. 2) facing each other and long sides 7d facing each other. Although only a device 8 is illustrated, a plurality of electronic components are mounted on a front surface 7a or a back surface 7b of the circuit board 7. Among the electronic components, the device 8 is a heat generating element that is highly integrated and generates a relatively large amount of heat such as a chipset, a multi-core CPU, and the like. The device 8 is provided thereon with a heat receiver 9 and a heat pipe 10. The heat receiver 9 and the heat pipe 10 are pushed against the device 8 by a pushing member 11. The pushing member 11 is formed by bending a metal plate or the like into a predetermined shape. A wiring pattern formed on the front surface 7a or the back surface 7b of the circuit board 7 is not illustrated.

In a plan view, the device 8 is formed in a square shape. In a plan view, the heat receiver 9 is formed in a flat plate-like or cuboid square shape in substantially the same size as the device 8. The heat receiver 9 is made of a material having a relatively high thermal conductivity such as silver, copper, gold, aluminum, brass, iron, or an alloy of any of these. A grease, a heat-receiving or heatsink sheet, or the like may be provided between the device 8 and the heat receiver 9.

The cross section of a heat receiving portion 10a of the heat pipe 10 is slightly dented in a component stack direction perpendicular to the front surface 7a of the circuit board 7. In the first embodiment, the pushing member 11 pushes the heat receiving portion 10a against the device 8, and thereby the heat receiver 9 is pushed against the device 8 together with the heat receiving portion 10a.

The heat pipe 10 is provided therein with a refrigerant that evaporates when heated and condenses when cooled. The refrigerant located on the heat receiver 9 side in the heat pipe 10 (i.e., in the heat receiving portion 10a) evaporates when heated by the heat receiver 9 and becomes a gas. The gas flows in the heat pipe 10 toward a heat dissipator 13. The refrigerant located on the heat dissipator 13 side in the heat pipe 10 (i.e., in a heat dissipating portion 10b) condenses when cooled by the heat dissipator 13 and becomes liquid. The liquid refrigerant flows back to the heat receiver 9 side in the heat pipe 10 by capillarity. In this manner, the refrigerant flows back and forth between the heat receiver 9 and the heat dissipator 13 in the heat pipe 10 while repeatedly evaporating and condensing. Accordingly, heat generated by the device 8 is transferred to the heat dissipator 13 via the heat receiver 9 and the heat pipe 10, and is dissipated from the heat dissipator 13.

As illustrated in FIG. 2, the pushing member 11 comprises a pushing portion 11b at the center and an arm 11a extending in three directions in a Y shape in a plan view. Besides, as illustrated in FIG. 3, the pushing member 11 is formed in M shape in a side view. The end of each leg of the arm 11a is bent to form an attaching portion 11c that extends along a bottom wall 2c of the housing 2a. A through hole (not illustrated), such as a circular hole, an elongated hole, a notch, etc., is formed in the attaching portion 11c. An attaching element such as a screw 14 passes through the through hole and is threaded into a boss 2f as an attached element provided on the bottom wall 2c of the housing 2a. In other words, in the first embodiment, the pushing member 11 is attached to the housing 2a. A female screw hole is formed in the boss 2f. In the first embodiment, the housing 2a is a non-board structure, i.e., a structure other than and independent of the circuit board 7. The non-board structure includes those other than the circuit board 7 and components, members, and the like (for example, electronic component, stud, etc.) attached to the circuit board 7.

When assembled as illustrated in FIGS. 2 and 3, the pushing member 11 elastically deforms. The elastic force of the pushing member 11 acts on at least one of the heat receiver 9 and the heat pipe 10 (in the first embodiment, the heat receiving portion 10a of the heat pipe 10) from the upper side to the lower side in FIG. 3 as a pushing force. The pushing force pushes the heat receiver 9 against the heat pipe 10. That is, the pushing member 11 functions as a leaf spring, and is preferably made of an elastic plate material (for example, spring steel, stainless steel, etc.). The pushing member 11 is further preferably made of a material having a high thermal conductivity.

The heat dissipating portion 10b of the heat pipe 10 is provided with the heat dissipator 13 having a plurality of fins 13a. The heat transferred through the heat pipe 10 from the heat receiving portion 10a to the heat dissipating portion 10b is dissipated from the heat dissipating portion 10b and the heat dissipator 13 to the surrounding air.

The heat dissipating portion 10b and the heat dissipator 13 are located near an opening 2e formed in a side wall 2d of the housing 2a. The cool air blower mechanism 12 is located opposite the opening 2e with respect to the heat dissipating portion 10b. The cool air blower mechanism 12 rotates a fan 12a to discharge air drawn in from the inside Is of the housing 2a through an air inlet 12b from an air outlet 12c. The air discharged from the air outlet 12c comes in contact with the heat dissipating portion 10b and the heat dissipator 13 and cools them. Then, the air is discharged from the opening 2e to the outside Os of the housing 2a. In other words, the air flow promotes heat exhaustion from the heat dissipating portion 10b and the heat dissipator 13. In the first embodiment, the heat receiver 9, the heat pipe 10, and the heat dissipator 13 form a heat dissipation mechanism 20. The pushing member 11 pushes part of the heat dissipation mechanism 20 against the device 8.

In the first embodiment, a reinforcing member 15 is located adjacent to the back surface 7b of the circuit board 7. As illustrated in FIG. 4, the reinforcing member 15 comprises a frame 15a formed in a rectangular ring shape. The frame 15a is arranged along the periphery of the rectangular device 8. The reinforcing member 15 further comprises arms 15b extending from the frame 15a toward the boss 2f. A through hole 15d is formed in an end 15c of each of the arms 15b. The screw 14 as an attaching element for the pushing member 11 is screwed into the through hole 15d. In other words, the reinforcing member 15 is attached to the boss 2f by the screw 14 together with the pushing member 11.

According to the first embodiment, as illustrated in FIGS. 2 and 3, all the attaching portions 11c of the pushing member 11 are attached to not the circuit board 7 but the bosses 2f of the housing 2a as a non-board structure. If the attaching portions 11c of the pushing member 11 are attached to the circuit board 7, attached portions need to be secured on the front surface 7a or the back surface 7b of the circuit board 7 correspondingly to the attaching portions 11c. An electronic component or a wiring pattern cannot be laid out on the attached portions. That is, this reduces the efficiency of mounting an electronic component or a wiring pattern on the circuit board 7. In view of this, in the first embodiment, the attaching portions 11c are attached to the housing 2a as a non-board structure to avoid reduction in the efficiency of mounting an electronic component or a wiring pattern on the front surface 7a or the back surface 7b of the circuit board 7. Particularly, if the electronic device 1 is small, further increased efficiency is required to mount an electronic component or a wiring pattern on the circuit board 7, and this structure is effective.

According to the first embodiment, as illustrated in FIG. 2, the pushing member 11 extends across the circuit board 7 in a direction intersecting the long sides 7d of the circuit board 7. Compared to the case where the pushing member 11 extends across the circuit board 7 in a direction intersecting the short sides 7c, the pushing member 11 can be formed smaller. In addition, since the bridge portion can be shorter, a larger pushing force can be generated.

According to the first embodiment, the reinforcing member 15 is located on the opposite side of the front surface 7a (on the back surface 7b) of the circuit board 7 where the device 8 is mounted. The reinforcing member 15 is attached to the housing 2a together with the pushing member 11, and therefore can receive load due to a pushing force applied from the pushing member 11. This reduces load on the housing 2a and the circuit board 7, thereby preventing bending deformation or the like of the housing 2a and the circuit board 7.

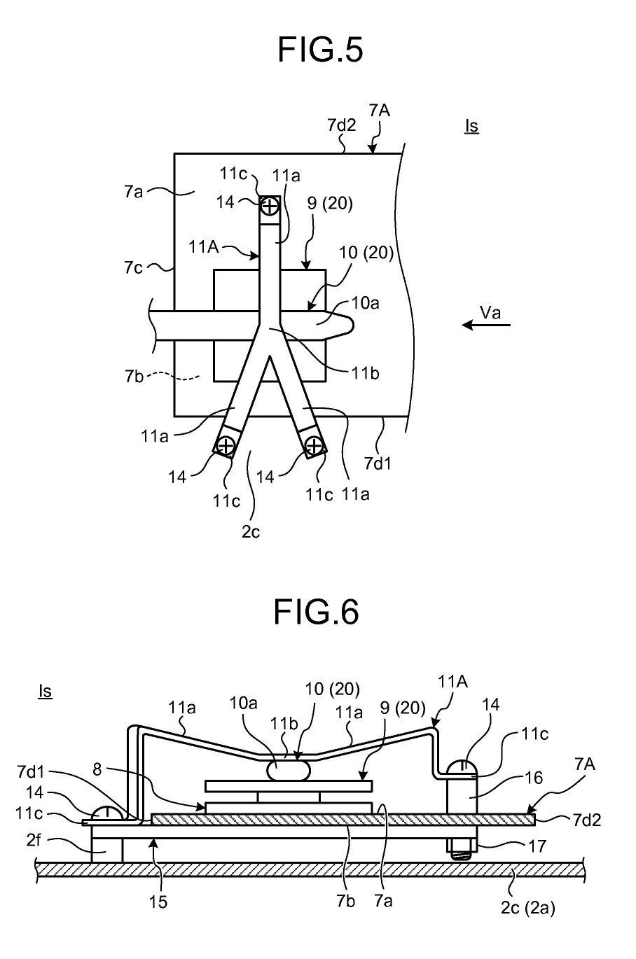

With reference to FIGS. 5 and 6, a description will be given of an electronic device according to a second embodiment.

As illustrated in FIGS. 5 and 6, in the second embodiment, one of the attaching portions 11c of the pushing member 11 (the attaching portion 11c on the upper side of FIG. 5) is attached to not the housing 2a but the circuit board 7A. A stud 16 is attached on the front surface 7a of the circuit board 7A, and the attaching portion 11c is attached to the stud 16 with an attaching element such as the screw 14. The stud 16 can be fixed to the circuit board 7A by, for example, tightening the male screw portion passing through the circuit board 7A and the reinforcing member 15 into a nut 17. In this structure, the other attaching portions 11c can also be attached to the housing 2a. Thus, the same effect as the first embodiment can be achieved.

According to the second embodiment, as illustrated in FIGS. 5 and 6, among mutually facing sides 7d1 and 7d2 of the circuit board 7A, the device 8 is located near the side 7d1. A pushing member 11A extends across the device 8 in a direction intersecting the sides 7d1 and 7d2. Among the attaching portions 11c of the pushing member 11A, the attaching portion 11c on the side 7d1 side (the attaching portion 11c closer to the side 7d1 than to the side 7d2) is attached to the boss 2f of the housing 2a. Meanwhile, the attaching portion 11c on the side 7d2 side (the attaching portion 11c closer to the side 7d2 than to the side 7d1) is attached to the stud 16 of the circuit board 7A. If the attaching portion 11c on the side 7d2 side is attached to the housing 2a outside the circuit board 7A, the arm 11a of the pushing member 11A needs to be longer. As a result, it may be difficult to ensure the pushing force of the pushing member 11A. In the second embodiment, the attaching portion 11c on the side 7d2 side more distant from the device 8 is attached to the circuit board 7A, and therefore the arm 11a can be sorter. In other words, this facilitates to avoid a situation where the long arm 11a makes it difficult to ensure the pushing force.

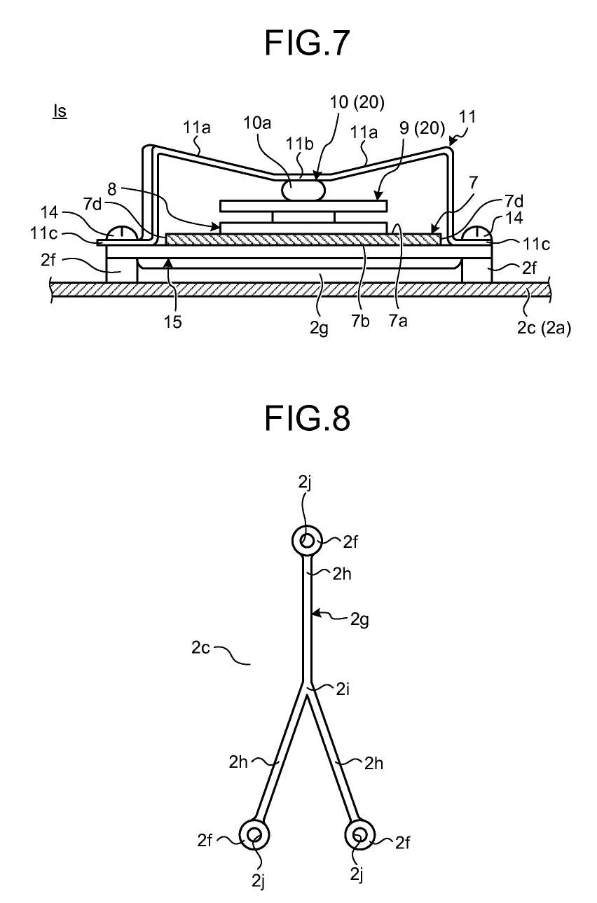

With reference to FIGS. 7 and 8, a description will be given of an electronic device according to a third embodiment.

As illustrated in FIGS. 7 and 8, in the third embodiment, a rib 2g is formed on the inner surface of the bottom wall 2c of the housing 2a as a structure reinforcing member (housing reinforcing member). The rib 2g is provided as a vertical wall having substantially constant width and height that connects between the bosses 2f as a plurality of attached portions. The rib 2g comprises three branches 2h each extending in a straight line from a center 2i toward each of the bosses 2f and formed in a Y shape. The center 2i overlaps the pushing portion 11b of the pushing member 11 in a plan view horizontal to the front surface 7a of the circuit board 7. A female screw hole 2j is formed in each of the bosses 2f.

According to the third embodiment, the same effect as the first embodiment can be achieved. Moreover, the housing 2a can be reinforced with the rib 2g as a structure reinforcing member. Therefore, it is possible to prevent deformation of the bottom wall 2c of the housing 2a and the circuit board 7 due to the elastic force of the pushing member 11. Furthermore, a structure reinforcing member can be obtained with a relatively simple structure as a rib that connects between the bosses 2f, i.e., a plurality of attached portions.

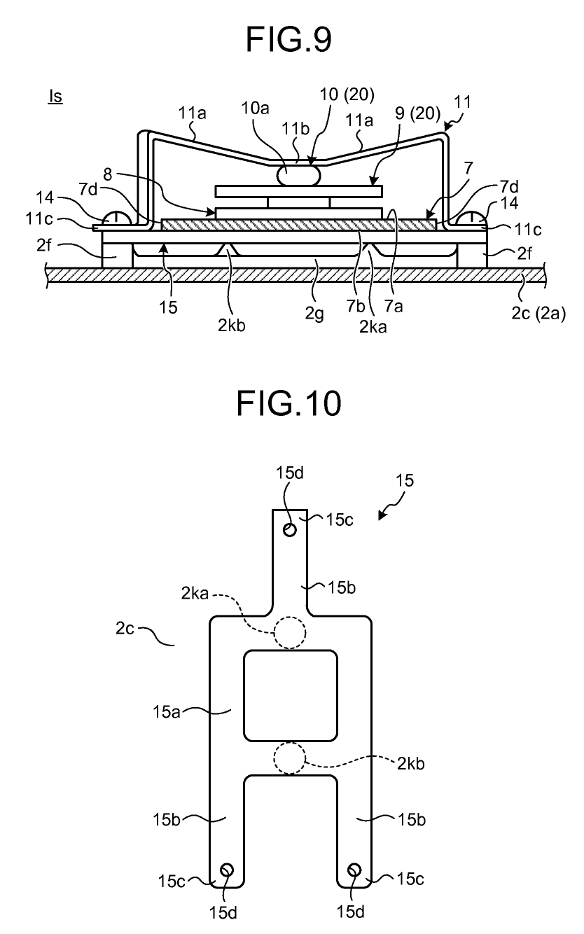

With reference to FIGS. 9 and 10, a description will be given of an electronic device according to a fourth embodiment.

As illustrated in FIGS. 9 and 10, in the fourth embodiment, protrusions 2ka and 2 kb are formed on the inner surface of the bottom wall 2c of the housing 2a as board supporting members that support the circuit board 7 at different positions than the bosses 2f. The protrusion 2ka is integrated with the rib 2g and supports the reinforcing member 15. That is, the protrusion 2ka indirectly supports the circuit board 7. The protrusion 2ka is located on the inner surface of the bottom wall 2c of the housing 2a independently of the rib 2g and supports the reinforcing member 15. That is, the protrusion 2ka also indirectly supports the circuit board 7.

According to the fourth embodiment, the same effect as the first and the third embodiments can be achieved. Moreover, the protrusions 2ka and 2 kb support the circuit board 7 as board supporting members. Therefore, it is possible to prevent deformation of the bottom wall 2c of the housing 2a and the circuit board 7 due to the elastic force of the pushing member 11. Furthermore, the protrusion 2ka as a structure reinforcing member is integrated with the rib 2g, which increases the rigidity of the rib 2g. Thus, it is possible to increase the effect of preventing deformation of the bottom wall 2c of the housing 2a and the circuit board 7 with the rib 2g as a structure reinforcing member.

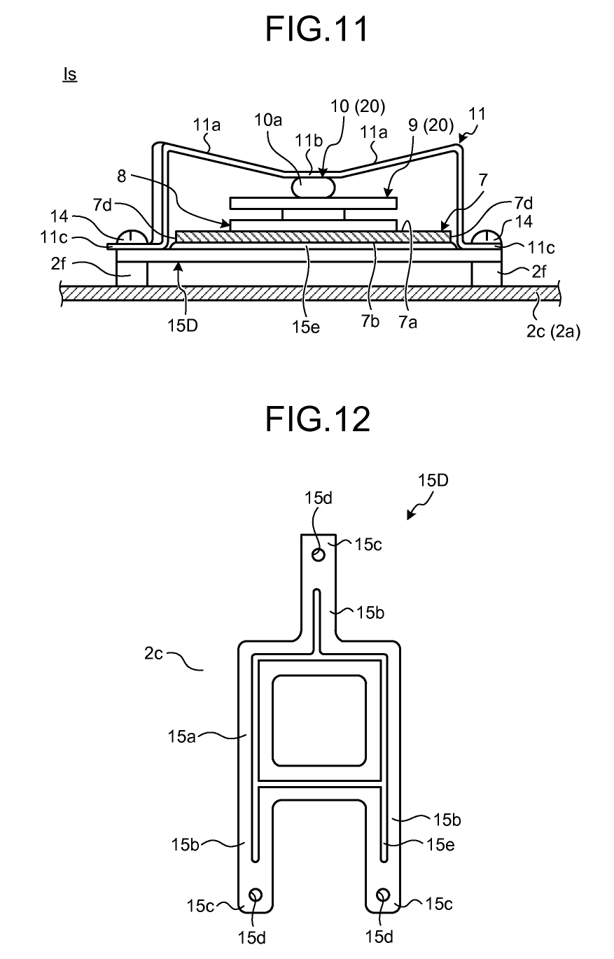

With reference to FIGS. 11 and 12, a description will be given of an electronic device according to a fifth embodiment.

As illustrated in FIGS. 11 and 12, in the fourth embodiment, a rib 15e is formed on a reinforcing member 15D that supports the circuit board 7 from the back surface 7b as a raised portion that is raised toward the circuit board 7. The rib 15e increases the rigidity of the reinforcing member 15D. Thus, it is possible to further increase the effect of preventing deformation of the bottom wall 2c of the housing 2a and the circuit board 7.

According to the fifth embodiment, compared with the case where the reinforcing member is provided with no rib as a raised portion and is entirely in contact with the back surface 7b of the circuit board 7, the contact area between the back surface 7b of the circuit board 7 and the reinforcing member 15D can be reduced. With this, the exposed area of the back surface 7b of the circuit board 7 can be increased. Thus, it is possible to improve the efficiency of mounting an electronic component or a wiring pattern on the circuit board 7.

While the electronic device of the embodiments is described above as a notebook personal computer, it may be any type of electronic device having a circuit board in the housing such as a television, a peripheral device thereof, or the like.

The heat generating element is not necessarily a device and the specification can be changed as per requirements. The specification (location, shape, size, thickness, material, etc.) can also be changed as required for the circuit board, the housing, the heat receiver, the heat pipe, the pushing member, the reinforcing member, the attached portion, the board supporting member, the structure reinforcing member, and the raised portion. The pushing member may be attaché to a non-board structure other than the housing.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic device comprising:
a circuit board in a housing;
a heat generator on the circuit board;
a heat dissipator configured to dissipate heat generated by the heat generator; and
a pressing portion configured to attach a portion of the heat dissipator to the heat generator, wherein
at least a portion of the pressing portion is attached to a structure other than the circuit board.

2. The electronic device of claim 1, wherein
a reinforcing module is provided on a surface of the circuit board opposite to where the heat generator is located, and
at least a portion of the reinforcing module and the pressing portion are attached to the structure.

3. The electronic device of claim 1, wherein
the circuit board is substantially in a rectangle having short sides facing each other and long sides facing each other, and
the pressing portion is configured to extend across the circuit board in a direction intersecting the long sides of the circuit board.

4. The electronic device of claim 1, wherein the structure comprises:
an attached portion where the pressing portion is attached; and
a supporter configured to support the circuit board at a different position than the attached portion.

5. The electronic device of claim 1, wherein the structure comprises:
a plurality of attached portions where the pressing portion is attached; and
a structure reinforcing module between the attached portions.

6. The electronic device of claim 5, wherein the structure reinforcing module is a rib on a surface of the structure and connecting between the attached portions.

7. The electronic device of claim 5, wherein the structure further comprises a supporter integrated with the structure reinforcing module, the supporter configured to support the circuit board at a different position than the attached portions.

8. The electronic device of claim 2, wherein the reinforcing module comprises a raised portion toward the circuit board.

9. The electronic device of claim 1, wherein a portion of the pressing portion is attached to the circuit board.

10. The electronic device of claim 9, wherein
the circuit board comprises a first side and a second side facing each other,
the heat generator is located near the first side,
the pressing portion is configured to extend across the heat generator in a direction intersecting the first side and the second side,
an end of the pressing portion on a side of the first side is attached to the structure, and
an end of the pressing portion on a side of the second side is attached to the circuit board.

11. An electronic device comprising:
a housing;
a circuit board in the housing;
an electronic, heat generating component on the circuit board;
a heat radiator configured to dissipate the heat from the component; and
an elastic brace attached to a portion of the heat radiator and to the electronic component and to the housing.
